(19) United States
(12) Patent Application Publication
(10) Pub. No.: US 2015/0357496 A1
(43) Pub. Date: Dec. 10, 2015

(54) CORE-SHELL PARTICLE, UPCONVERSION LAYER, AND PHOTOELECTRIC CONVERSION DEVICE

(71) Applicant: SHARP KABUSHIKI KAISHA, Osaka-shi, Osaka (JP)

(72) Inventor: Kenji KIMOTO, Osaka-shi (JP)

(73) Assignee: SHARP KABUSHIKI KAISHA, Abeno-ku, Osaka-shi, Osaka (JP)

(21) Appl. No.: 14/761,708

(22) PCT Filed: Mar. 4, 2014
(86) PCT No.: PCT/JP2014/055395

§ 371 Date: Jul. 17, 2015

(30) Foreign Application Priority Data
Mar. 5, 2013 (JP) 2013-043023

(51) Int. Cl. H01L 31/055; C09K 11/62

(52) U.S. Cl. CPC H01L 31/055; C09K 11/623

(57) ABSTRACT

A core-shell particle including a semiconductor core and a first semiconductor shell on a surface of the semiconductor core, wherein the semiconductor core contains a semiconductor and an impurity that forms an intermediate band in a band gap of the semiconductor. An upconversion layer and a photoelectric conversion device each containing the core-shell particle.

### TECHNICAL FIELD

The present invention relates to a core-shell particle, an upconversion layer, and a photoelectric conversion device.

### BACKGROUND ART

In recent years, particularly from the perspective of global environmental issues, solar cells that directly convert the energy of sunlight into electrical energy have been highly anticipated to be next-generation energy sources. There are various types of solar cells, for example, crystalline silicon, amorphous silicon, compound semiconductor, and organic material solar cells. Among these, crystalline silicon solar cells are currently in the mainstream.

Solar cells are generally produced by diffusing an impurity in a light-receiving surface of a single-crystal or polycrystalline silicon wafer to form a photoelectric conversion layer having a pn junction and forming electrodes on the light-receiving surface of the photoelectric conversion layer and on the back side of the photoelectric conversion layer opposite the light-receiving surface. The impurity is of an opposite conductivity type to the crystalline silicon wafer.

Solar cells that do not have an electrode on the light-receiving surface of the photoelectric conversion layer but has an electrode on the back side of the photoelectric conversion layer are also under development.

In existing solar cells, light having lower energy than the band-gap energy of the photoelectric conversion layer is not absorbed by the photoelectric conversion layer and causes large photoelectric conversion loss. Thus, for example, a solar cell having a wavelength conversion layer containing composite particles is proposed in Patent Literature 1.

The composite particles in the wavelength conversion layer of the solar cell described in Patent Literature 1 include semiconductor particles and inorganic compound particles having a different composition from the semiconductor particles. The inorganic compound particles contain a rare earth element and an alkali metal element.

Depending on the type of rare earth element, the wavelength conversion layer can perform wavelength conversion to short wavelengths (upconversion). The solar cell described in Patent Literature 1 thereby converts light in a long-wavelength region unsuitable for photoelectric conversion into light in a short-wavelength region available for photoelectric conversion, thereby reducing photoelectric conversion loss and improving photoelectric conversion efficiency.

### CITATION LIST

### Patent Literature

PTL 1: Japanese Unexamined Patent Application Publication No. 2011-116594

### SUMMARY OF INVENTION

### Technical Problem

However, the wavelength conversion layer described in Patent Literature 1 that can perform upconversion has low upconversion efficiency and cannot be practically used.

In view of such situations, it is an object of the present invention to provide a core-shell particle, an upconversion layer, and a photoelectric conversion device that can improve upconversion efficiency and improve the photoelectric conversion efficiency of the photoelectric conversion device.

### Solution to Problem

The present invention provides a core-shell particle that includes a semiconductor core and a first semiconductor shell on a surface of the semiconductor core, wherein the semiconductor core contains a semiconductor and an impurity that forms an intermediate band in a band gap of the semiconductor. In such a structure, when excitation light enters the semiconductor constituting the semiconductor core, an electron in the valence band in the semiconductor core absorbs light having a wavelength corresponding to the energy difference between the intermediate band and the valence band and light having a wavelength corresponding to the energy difference between the conduction band and the intermediate band and is excited to the conduction band via the intermediate band, forming an electron-hole pair. The electron-hole pair flows into the first semiconductor shell, recombines, and emits light having a wavelength corresponding to the band gap of the first semiconductor shell, thus performing upconversion.

The present invention also provides an upconversion layer containing the core-shell particle. Such a structure can provide an upconversion layer that can improve upconversion efficiency and improve the photoelectric conversion efficiency of photoelectric conversion devices.

The present invention also provides a photoelectric conversion device that includes a photoelectric conversion layer and the upconversion layer disposed on a surface of the photoelectric conversion layer. Such a structure can provide a photoelectric conversion device that can improve upconversion efficiency and photoelectric conversion efficiency.

### Advantageous Effects of Invention

The present invention can provide a core-shell particle, an upconversion layer, and a photoelectric conversion device that can improve upconversion efficiency and improve the photoelectric conversion efficiency of the photoelectric conversion device.

### BRIEF DESCRIPTION OF DRAWINGS

FIG. 1 is a schematic cross-sectional view of a core-shell particle according to an embodiment of the present invention.

FIG. 2 is a correlation diagram of preferred band gaps between the semiconductor core, the first semiconductor shell, and the second semiconductor shell of a core-shell particle according to the present invention.

FIG. 3 (a) to (c) are schematic cross-sectional views illustrating a method for producing a core-shell particle according to an embodiment of the present invention.

FIG. 4 is a graph of lattice constant changes and band-gap energy changes for different compositions of the first semiconductor shell of a core-shell particle according to the present invention.

FIG. 5 is a schematic cross-sectional view of a photoelectric conversion device according to an embodiment of the present invention.

FIG. 6 is a schematic side view illustrating a method for producing a semiconductor core according to an example of the present invention.

[FIG. 7](a) to (c) are schematic cross-sectional views illustrating a method for producing a photovoltaic cell according to Example 1.

[FIG. 8](a) to (c) are schematic cross-sectional views illustrating a method for producing a photovoltaic cell according to Example 2.

[FIG. 9](a) to (c) are schematic cross-sectional views illustrating a method for producing a photovoltaic cell according to Example 3.

[FIG. 10](a) to (c) are schematic cross-sectional views illustrating a method for producing a photovoltaic cell according to Example 4.

[FIG. 11](a) to (c) are schematic cross-sectional views illustrating a method for producing a photovoltaic cell according to Example 5.

FIG. 12 is a graph showing the relationship between the band-gap energy of a semiconductor core of a core-shell particle in an upconversion layer of photovoltaic cells according to Examples 6 to 9 and internal quantum efficiency.

FIG. 13 is a schematic view of the structure of a photoelectric conversion module according to an embodiment of the present invention.

FIG. 14 is a schematic view of the structure of a photovoltaic power generation system according to an embodiment of the present invention.

FIG. 15 is a schematic view of a structure of a photoelectric conversion module array illustrated in FIG. 14.

FIG. 16 is a schematic view of the structure of a large-scale photovoltaic power generation system according to an embodiment of the present invention.

FIG. 17 is a schematic view of the structure of a photovoltaic power generation system according to another embodiment of the present invention.

FIG. 18 is a schematic view of the structure of a large-scale photovoltaic power generation system according to another embodiment of the present invention.

### DESCRIPTION OF EMBODIMENTS

Embodiments of the present invention will be described below. Like reference numerals denote like parts or equivalents thereof throughout the figures. The composition formula of a preferred compound in an embodiment of the present invention represents the typical composition of the compound. When the difference between the composition percentage of each element in a substance and the composition percentage of the corresponding element of the composition formula is within approximately ±20% or less, the substance is considered to be a compound represented by the composition formula.

### <Core-Shell Particle>

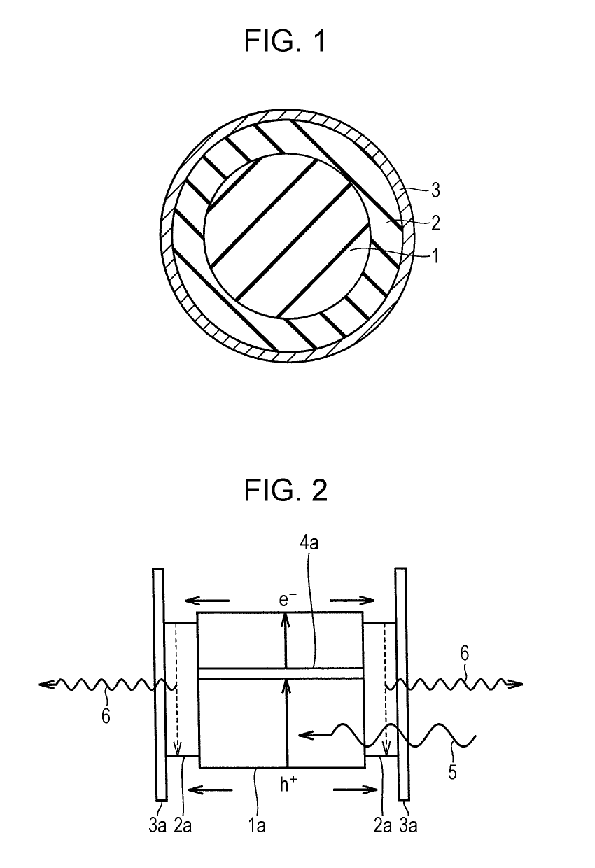

FIG. 1 is a schematic cross-sectional view of a core-shell particle according to an embodiment of the present invention. The core-shell particle illustrated in FIG. 1 includes a semiconductor core 1, a first semiconductor shell 2 on the surface of the semiconductor core 1, and a second semiconductor shell 3 on the surface of the first semiconductor shell 2.

### <Semiconductor Core>

The semiconductor core 1 contains a semiconductor and an impurity that forms an intermediate band in a band gap of the semiconductor. Thus, when excitation light enters the semiconductor constituting the semiconductor core 1, an electron in the valence band in the semiconductor core 1 absorbs light having a wavelength corresponding to the energy difference between the intermediate band and the valence band and light having a wavelength corresponding to the energy difference between the conduction band and the intermediate band and is excited to the conduction band via the intermediate band, forming an electron-hole pair. The electron-hole pair flows into the first semiconductor shell 2, recombines, and emits light having a wavelength corresponding to the band gap of the first semiconductor shell 2, thus performing upconversion.

The semiconductor constituting the semiconductor core 1 preferably contains copper (Cu), at least one of gallium (Ga) and indium (In), and at least one of sulfur (S) and selenium (Se). For example, the semiconductor constituting the semiconductor core 1 is preferably represented by CuGa₁₋ₓ₁Inₓ₁S_{2-2y1}Se_{2y1} (0≦x1≦1, 0≦y1≦1), particularly CuGaS₂. This can further improve the upconversion efficiency of electrons excited by irradiation with excitation light in the semiconductor core 1.

The impurity that forms an intermediate band in a band gap of the semiconductor constituting the semiconductor core 1 is preferably at least one selected from the group consisting of carbon (C), silicon (Si), germanium (Ge), tin (Sn), titanium (Ti), iron (Fe), and chromium (Cr). This results in the formation of the semiconductor core 1 having less crystal defects, allows electrons in the semiconductor core 1 to be efficiently excited by irradiation with excitation light, and further improves upconversion efficiency.

The average particle size of the semiconductor core 1, the average particle size of the semiconductor core 1 preferably ranges from 5 to 25 nm, more preferably 8 to 15 nm. When the semiconductor core 1 has an average particle size in the range of 5 to 25 nm, particularly 8 to 15 nm, an impurity that forms an intermediate band can be introduced into the semiconductor constituting the semiconductor core 1 with little abnormalities, such as segregation of impurity atoms, thus facilitating the formation of the semiconductor core 1 havinonductor core 1 to be efficiently excited by irradiation with excitation light, allows more carriers generated by irradiation with excitation light in the semiconductor core 1 to flow into the first semiconductor shell 2, and further improves upconversion efficiency.

The average particle size of the semiconductor core 1 can be determined with a transmission electron microscope, for example. More specifically, core-shell particles according to the present invention are dispersed on an observation mesh of a transmission electron microscope. A cross section of the dispersed core-shell particles is observed under appropriate magnification. A hundred of the semiconductor cores 1 of the core-shell particles in the observed image are randomly chosen to determine the sum total of the cross-sectional areas of the semiconductor cores 1. The average particle size of the semiconductor core 1 is equivalent to the diameter of a circle having the same area as the area calculated by dividing the sum total by 100.

The amount of impurity that forms an intermediate band in the semiconductor core 1 preferably ranges from 0.2 to 10 atomic percent, more preferably 1 to 3 atomic percent, of the semiconductor core 1. When the amount of impurity that forms an intermediate band in the semiconductor core 1 ranges from 0.2 to 10 atomic percent, particularly 1 to 3 atomic percent, it is easy to form the semiconductor core 1 having less crystal defects. This allows electrons in the semiconductor core 1 to be efficiently excited by irradiation with excitation light, allows more carriers generated by irradiation with excitation light in the semiconductor core 1 to flow into the first semiconductor shell 2, and further improves upconversion efficiency.

### <First Semiconductor Shell>

The first semiconductor shell 2 is preferably a direct transition semiconductor. In this case, when an electron excited by irradiation with excitation light in the semiconductor core 1 recombines with a positive hole in the first semiconductor shell 2, light having a shorter wavelength than the excitation light can be efficiently emitted from the first semiconductor shell 2.

The band gap of the first semiconductor shell 2 is preferably narrower than the band gap of the semiconductor core 1. More preferably, at least one of the lower end of the conduction band and the upper end of the valence band of the first semiconductor shell 2 is closer to the intermediate band than the corresponding lower end of the conduction band and the corresponding upper end of the valence band of the semiconductor core 1. Still more preferably, the lower end of the conduction band and the upper end of the valence band of the first semiconductor shell 2 are closer to the intermediate band than the corresponding lower end of the conduction band and the corresponding upper end of the valence band of the semiconductor core 1. Such a structure allows carriers generated in the semiconductor core 1 to flow easily into the first semiconductor shell 2 and can effectively prevent the carriers from flowing backward from the first semiconductor shell 2 to the semiconductor core 1. This can increase the amount of light emitted from the first semiconductor shell 2 and improve the photoelectric conversion efficiency of a photoelectric conversion device including a core-shell particle according to the present invention.

The first semiconductor shell 2 is preferably made of a semiconductor containing Cu, at least one of Ga and In, and at least one of S and Se. For example, the first semiconductor shell 2 is more preferably made of a semiconductor represented by CuGa₁₋ₓ₂Inₓ₂S_{2-2y2}Se_{2y2} (0≦x2≦1, 0≦y2≦1) and is particularly preferably made of a semiconductor represented by at least one formula selected from the group consisting of CuGaS₂, CuInS₂, CuGa_{1 x2}Inₓ₂S₂ (0<x2<1), and CuGaS_{2-2y2}Se_{2y2} (0<y2<1). These semiconductors are direct transition semiconductors and have high luminous efficiency. In particular, when the semiconductor core 1 is made of a semiconductor containing copper (Cu), at least one of gallium (Ga) and indium (In), and at least one of sulfur (S) and selenium (Se), this can reduce the likelihood of lattice mismatch at the interface between the semiconductor core 1 and the first semiconductor shell 2 and significantly reduce carrier recombination at the interface. An electron excited by irradiation with excitation light in the semiconductor core 1 recombines with a positive hole in the first semiconductor shell 2. Excitation light can be efficiently converted into light having a shorter wavelength than the excitation light before entering a photoelectric conversion layer of a photoelectric conversion device. Thus, the photoelectric conversion device can have further improved photoelectric conversion efficiency. Unlike the semiconductor core 1, it is not necessary to form an intermediate band in the first semiconductor shell 2. Thus, an impurity that forms an intermediate band is not needed in the first semiconductor shell 2.

When the semiconductors of the semiconductor core 1 and the first semiconductor shell 2 are represented by CuGa₁ₓ₁Inₓ₁S_{2-2y1}Se_{2y1} (0≦x1≦1, 0≦y1≦1) and CuGa₁₋ₓ₂Inₓ₂S_{2-2y2}Se_{2y2} (0≦x2≦1, 0≦y2≦1), respectively, the In and/or Se content (atomic percent) is preferably higher in the first semiconductor shell 2 than in the semiconductor constituting the semiconductor core 1 (x2>x1 and/or y2>y1). In such a case, the band gap of the first semiconductor shell 2 is narrower than the band gap of the semiconductor constituting the semiconductor core 1, and one or both of the lower end of the conduction band and the upper end of the valence band of the first semiconductor shell 2 are closer to the intermediate band than the corresponding lower end of the conduction band and the corresponding upper end of the valence band of the semiconductor constituting the semiconductor core 1. This allows carriers generated in the semiconductor core 1 to flow easily into the first semiconductor shell 2 and can more effectively prevent the carriers from flowing backward from the first semiconductor shell 2 to the semiconductor core 1.

The first semiconductor shell 2 on the surface of the semiconductor core 1 preferably has a thickness in the range of 4 to 50 nm, more preferably 5 to 15 nm. When the first semiconductor shell 2 on the surface of the semiconductor core 1 has a thickness in the range of 4 to 50 nm, particularly 5 to 15 nm, this can increase the amount of light emitted from the first semiconductor shell 2 and efficiently prevent carriers from flowing from the first semiconductor shell 2.

The thickness of the first semiconductor shell 2 can be determined with a transmission electron microscope, for example. More specifically, core-shell particles according to the present invention are dispersed on an observation mesh of a transmission electron microscope. A cross section of the dispersed core-shell particles is observed under appropriate magnification. The thickness of the first semiconductor shell 2 in the core-shell particles in the observed image is measured. <Second Semiconductor Shell>

Preferably, the second semiconductor shell 3 is disposed on the surface of the first semiconductor shell 2. The second semiconductor shell 3 can reduce carriers flowing from the first semiconductor shell 2 into the second semiconductor shell 3 and increase the amount of light emitted from the first semiconductor shell 2.

The band gap of the second semiconductor shell 3 is preferably wider than the band gap of the first semiconductor shell 2. More preferably, at least one of the lower end of the conduction band and the upper end of the valence band of the second semiconductor shell 3 is more distant from the intermediate band than the corresponding lower end of the conduction band and the corresponding upper end of the valence band of the first semiconductor shell 2. Still more preferably, the lower end of the conduction band and the upper end of the valence band of the second semiconductor shell 3 are more distant from the intermediate band than the corresponding lower end of the conduction band and the corresponding upper end of the valence band of the first semiconductor shell 2. The second semiconductor shell 3 having such a structure can more effectively prevent carriers from flowing from the first semiconductor shell 2.

When the first semiconductor shell 2 is made of a semiconductor represented by the formula CuGa₁₋ₓ₂Inₓ₂S_{2-2y2}Se_{2y2} (0≦x2≦1, 0≦y2≦1), the second semiconductor shell 3 is preferably made of a semiconductor containing zinc and sulfur. For example, the second semiconductor shell 3 is preferably made of a semiconductor represented by the formula ZnSₓ (x=approximately 1) or Zn(S, O, OH). In such a case, the band gap of the second semiconductor shell 3 is wider than the band gap of the first semiconductor shell 2, and the lower end of the conduction band and the upper end of the valence band of the second semiconductor shell 3 are more distant from the intermediate band than the corresponding lower end of the conduction band and the corresponding upper end of the valence band of the first semiconductor shell 2. This can more effectively prevent carriers in the first semiconductor shell 2 from flowing from the second semiconductor shell 3.

The second semiconductor shell 3 on the surface of the first semiconductor shell 2 preferably has a thickness in the range of 4 to 50 nm, more preferably 5 to 15 nm. When the second semiconductor shell 3 on the surface of the first semiconductor shell 2 has a thickness in the range of 4 to 50 nm, particularly 5 to 15 nm, the second semiconductor shell 3 can more effectively prevent carriers from flowing from the first semiconductor shell 2.

The thickness of the second semiconductor shell 3 can be determined with a transmission electron microscope, for example. More specifically, core-shell particles according to the present invention are dispersed on an observation mesh of a transmission electron microscope. A cross section of the dispersed core-shell particles is observed under appropriate magnification. The thickness of the second semiconductor shell 3 in the core-shell particles in the observed image is measured.

### <Wavelength Conversion Mechanism>

FIG. 2 is a correlation diagram of preferred band gaps between the semiconductor core 1, the first semiconductor shell 2, and the second semiconductor shell 3 of a core-shell particle according to the present invention. The band gap 2a of the first semiconductor shell 2 is narrower than the band gap of the semiconductor constituting the semiconductor core 11a. The lower end of the conduction band and the upper end of the valence band of the first semiconductor shell 2 are closer to the intermediate band 4a than the corresponding lower end of the conduction band and the corresponding upper end of the valence band of the semiconductor constituting the semiconductor core 1. The band gap 3a of the second semiconductor shell 3 is wider than the band gap 2a of the first semiconductor shell 2. The lower end of the conduction band and the upper end of the valence band of the second semiconductor shell 3 are more distant from the intermediate band 4a than the corresponding lower end of the conduction band and the corresponding upper end of the valence band of the first semiconductor shell 2.

In the core-shell particle having the band gap correlation illustrated in FIG. 2, when excitation light 5 having lower energy than the band gap of the semiconductor constituting the semiconductor core 1 enters the semiconductor core 1, an electron excited by absorbing the energy of the excitation light 5 in the semiconductor constituting the semiconductor core 1 releases a positive hole to the valence band of the semiconductor constituting the semiconductor core 1 and is excited to the intermediate band formed by an impurity added to the semiconductor constituting the semiconductor core 1.

When additional excitation light 5 enters the semiconductor core 1, an electron in the intermediate band absorbs energy from the excitation light 5 and is excited to the conduction band of the semiconductor constituting the semiconductor core 1.

The electron excited to the conduction band of the semiconductor constituting the semiconductor core 1 and a positive hole in the valence band of the semiconductor flow into the corresponding conduction band and the corresponding valence band of the first semiconductor shell 2 having a low band gap adjacent to the semiconductor core 1. The electron and the positive hole recombine in the first semiconductor shell 2 and emit light 6 having energy corresponding to the band-gap energy of the first semiconductor shell 2 from the first semiconductor shell 2. Thus, the wavelength of the light 6 emitted from the first semiconductor shell 2 is shorter than the wavelength of the excitation light 5 entering the semiconductor core 1.

As illustrated in FIG. 2, when the lower end of the conduction band and the upper end of the valence band of the first semiconductor shell 2 are closer to the intermediate band 4a than the corresponding lower end of the conduction band and the corresponding upper end of the valence band of the semiconductor constituting the semiconductor core 1 and the second semiconductor shell 3, this can effectively prevent carriers flowing into the first semiconductor shell 2 from flowing from the first semiconductor shell 2, thus increasing the amount of light 6 emitted from the first semiconductor shell 2. Thus, when a core-shell particle having a band gap correlation illustrated in FIG. 2 is used in a photoelectric conversion device, the core-shell particle can promote the conversion of light having a long wavelength that cannot be absorbed by a photoelectric conversion layer of the photoelectric conversion device into light having a short wavelength that can be absorbed by the photoelectric conversion layer of the photoelectric conversion device and allows the photoelectric conversion layer to absorb the light, thus improving the photoelectric conversion efficiency of the photoelectric conversion device. When at least one of the lower end of the conduction band and the upper end of the valence band of the first semiconductor shell 2 is closer to the intermediate band 4a than the corresponding lower end of the conduction band and the corresponding upper end of the valence band of the semiconductor constituting the semiconductor core 1, this can effectively prevent the flow of carriers (at least one of electrons and positive holes) flowing into the first semiconductor shell 2 (backflow into the semiconductor core 1), thus increasing the amount of light 6 emitted from the first semiconductor shell 2.

As illustrated in FIG. 2, when the lower end of the conduction band and the upper end of the valence band of the second semiconductor shell 3 are more distant from the intermediate band than the corresponding lower end of the conduction band and the corresponding upper end of the valence band of the first semiconductor shell 2, the second semiconductor shell 3 can more effectively prevent carriers from flowing from the first semiconductor shell 2, thereby increasing the amount of light 6 emitted from the first semiconductor shell 2. Thus, when a core-shell particle having a band gap interphase relation illustrated in FIG. 2 is used in a photoelectric conversion device, the core-shell particle can promote the conversion of light having a long wavelength that cannot be absorbed by a photoelectric conversion layer of the photoelectric conversion device into light having a short wavelength that can be absorbed by the photoelectric conversion layer of the photoelectric conversion device and allows the photoelectric conversion layer to absorb the light, thus improving the photoelectric conversion efficiency of the photoelectric conversion device. When at least one of the lower end of the conduction band and the upper end of the valence band of the second semiconductor shell 3 is distant from the intermediate band than the corresponding lower end of the conduction band and the corresponding upper end of the valence band of the first semiconductor shell 2, this can effectively prevent carriers (at least one of electrons and positive holes) from flowing from the first semiconductor shell 2 to the second semiconductor shell 3, thus increasing the amount of light 6 emitted from the first semiconductor shell 2.

### <Method for Producing Core-Shell Particle>

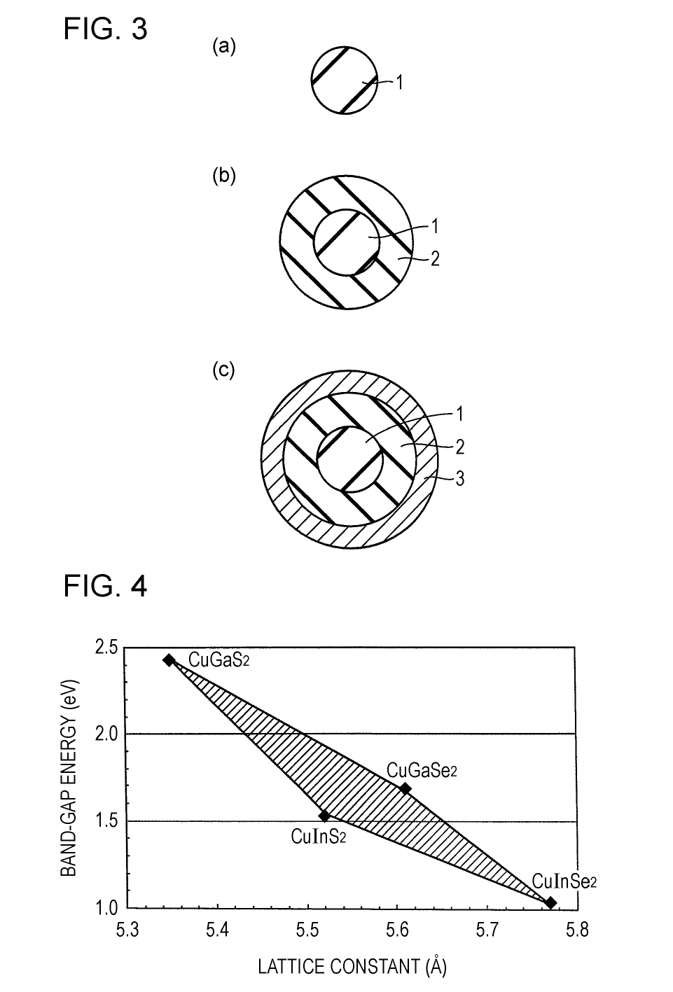

A method for producing a core-shell particle according to an embodiment of the present invention will be described below with reference to schematic cross-sectional views of FIGS. 3(a) to 3(c). First, as illustrated in FIG. 3(a), the semiconductor core 1 is formed. For example, the semiconductor core 1 can be formed as a precipitate through a reaction of raw powders of the semiconductor constituting the semiconductor core 1 and the impurity in a predetermined liquid phase, purification, and precipitation.

As illustrated in FIG. 3(b), the surface of the semiconductor core 1 is then covered with the first semiconductor shell 2. The surface of the semiconductor core 1 can be covered with the first semiconductor shell 2, for example, through a reaction of a raw powder of the first semiconductor shell 2 in a predetermined liquid phase, addition of the result in dispersion liquid of the precipitate of the semiconductor core 1, purification, and precipitation. The precipitate is a particle of the semiconductor core 1 covered with the first semiconductor shell 2.

FIG. 4 shows lattice constant and band-gap energy changes for different compositions of the first semiconductor shell 2. The first semiconductor shell 2 is made of a semiconductor represented by the formula CuGa₁₋ₓ₂Inₓ₂S_{2-2y2}Se_{2y2} (0≦x2≦1, 0≦y2≦1). As shown in FIG. 4, when the composition of the first semiconductor shell 2 is changed from CuGaS₂ to CuGaSe₂, to CuInS₂, and to CuInSe₂, the band-gap energy of the first semiconductor shell 2 can be gradually decreased from CuGaS₂ (2.43 eV) to CuGaSe₂ (1.68 eV), to CuInS₂ (1.53 eV), and to CuInSe₂ (1.04 eV).

The hatched area in FIG. 4 indicates the possible lattice constant and band-gap energy of the first semiconductor shell 2 made of the semiconductor represented by the formula CuGa₁₋ₓ₂Inₓ₂S_{2-2y2}Se_{2y2} (023 x2≦1, 0≦y2≦1).

As illustrated in FIG. 3(c), the surface of the first semiconductor shell 2 is then covered with the second semiconductor shell 3. The surface of the first semiconductor shell 2 can be covered with the second semiconductor shell 3, for example, through a reaction of a raw powder of the second semiconductor shell 3 in a predetermined liquid phase, addition of the resulting liquid to a dispersion liquid of the particle of the semiconductor core 1 covered with the first semiconductor shell 2, purification, and precipitation. The precipitate is a core-shell particle according to an embodiment of the present invention in which the surface of the semiconductor core 1 is covered with the first semiconductor shell 2, and the surface of the first semiconductor shell 2 is covered with the second semiconductor shell 3.

### <Upconversion Layer and Photoelectric Conversion Device>

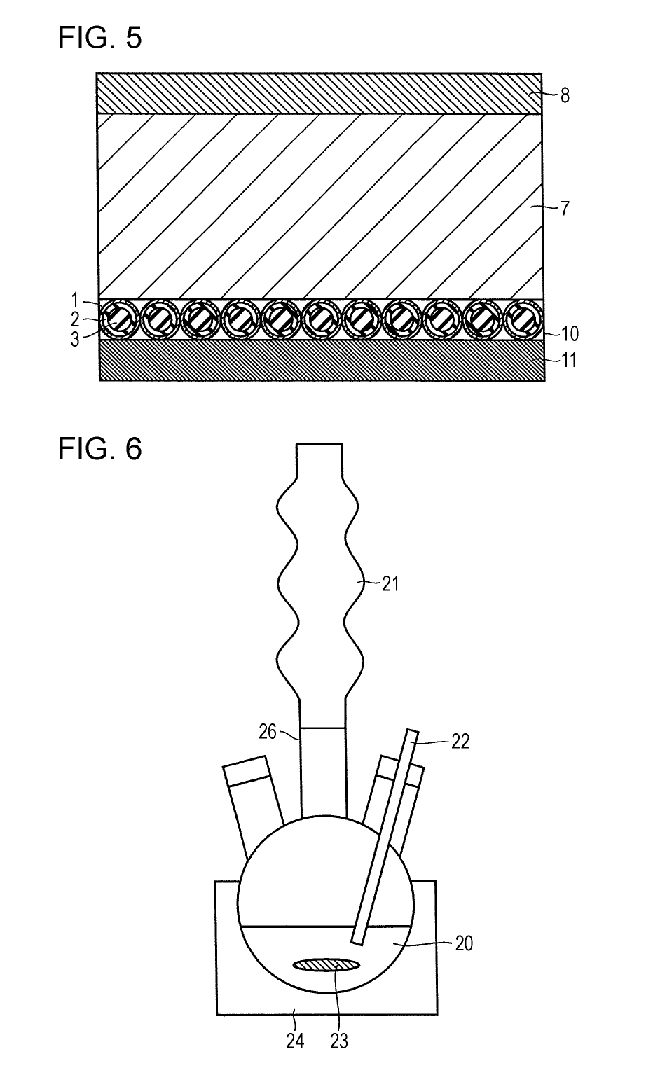

FIG. 5 is a schematic cross-sectional view of a photoelectric conversion device according to an embodiment of the present invention. As illustrated in FIG. 5, a photoelectric conversion device according to an embodiment of the present invention includes a photoelectric conversion layer 7, a light-receiving surface side electrode 8 on a light-receiving surface of the photoelectric conversion layer 7, a back-side electrode 11 on the back side of the photoelectric conversion layer 7, and an upconversion layer 10 between the photoelectric conversion layer 7 and the back-side electrode 11. The back-side electrode 11 is electrically connected to the photoelectric conversion layer 7, for example, through an opening in the upconversion layer 10.

For example, the upconversion layer 10 can be formed by preparing a dispersion liquid containing core-shell particles according to the present invention produced as described above dispersed in a predetermined liquid, applying the dispersion liquid to the back side of the photoelectric conversion layer 7, and drying the dispersion liquid. The upconversion layer 10 preferably has a thickness in the range of 0.5 to 10 μm, more preferably 1 to 3 v. When the upconversion layer 10 has a thickness in the range of 0.5 to 10 v, particularly 1 to 3 v, the upconversion layer 10 can absorb most of light entering the upconversion layer 10 and can effectively perform upconversion.

When light enters the photoelectric conversion layer 7 through the light-receiving surface of the photoelectric conversion device illustrated in FIG. 5, light having a long wavelength not absorbed by the photoelectric conversion layer 7 passes through the photoelectric conversion layer 7 and enters the upconversion layer 10. As described above, light entering the upconversion layer 10 excites an electron in the valence band of the semiconductor constituting the semiconductor core 1 of a core-shell particle according to the present invention to the conduction band via the intermediate band, allows the electron to recombine with a positive hole in the first semiconductor shell 2, and is emitted as light having a shorter wavelength from the upconversion layer 10. Light emitted from the upconversion layer 10 is reflected by the back-side electrode 11 on the back side of the photoelectric conversion layer 7 and is returned to the photoelectric conversion layer 7. Because light emitted from the upconversion layer 10 and reentering the photoelectric conversion layer 7 has been converted into light having a short wavelength by a core-shell particle according to the present invention, the light can be absorbed by the photoelectric conversion layer 7 and is converted into electrical energy. In particular, because the upconversion layer 10 of a photoelectric conversion device according to the present invention contains a core-shell particle according to the present invention having improved upconversion efficiency, light having a long wavelength entering the upconversion layer 10 can be more efficiently converted into light having a short wavelength. Thus, a photoelectric conversion device according to the present invention can have improved photoelectric conversion efficiency.

The surface on the side of the light-receiving surface of the photoelectric conversion layer 7 preferably has an antireflection structure or optical confinement structure, such as a textured structure. For example, the photoelectric conversion layer 7 may be made of single-crystal silicon, polycrystalline silicon, hydrogenated amorphous silicon, a compound of copper, indium, gallium, and selenium (CIGS), Cu₂ZnSnS₄ (CZTS), gallium arsenide (GaAs), or cadmium tellurium (CdTe). The material of the photoelectric conversion layer 7 is preferably determined such that the band gap of the first semiconductor shell 2 of a core-shell particle according to the present invention is greater than or equal to the band gap of the photoelectric conversion layer 7.

### <Photoelectric Conversion Module>

FIG. 13 is a schematic view of the structure of a photoelectric conversion module according to an embodiment of the present invention that includes a photoelectric conversion device according to the present invention. Referring to FIG. 13, a photoelectric conversion module 1000 according to the present invention includes a plurality of photoelectric conversion devices 1001, a cover 1002, and output terminals 1013 and 1014. A photoelectric conversion device according to the present invention has high conversion efficiency. Thus, a photoelectric conversion module and a photovoltaic power generation system according to the present invention including the photoelectric conversion device can also have high conversion efficiency.

The photoelectric conversion devices 1001 are arranged in an array and are connected in series. Although the photoelectric conversion devices 1001 are arranged for series connection in FIG. 13, the arrangement and connection are not limited to this. The photoelectric conversion devices 1001 may be coupled in parallel or in a combination of series and parallel. Each of the photoelectric conversion devices 1001 is a photoelectric conversion device according to the present invention. The number of the photoelectric conversion devices 1001 in the photoelectric conversion module 1000 may be an integer of 2 or more.

The cover 1002 is a weatherproof cover and covers the photoelectric conversion devices 1001. For example, the cover 1002 includes a transparent substrate (for example, glass) on the light-receiving surface of the photoelectric conversion devices 1001, a back substrate (for example, glass or resin sheet) on the back side of the photoelectric conversion devices 1001 opposite the light-receiving surface, and a sealant (for example, ethylene-vinyl acetate (EVA)) that fills the space between the transparent substrate and the back substrate.

The output terminal 1013 is coupled to one end of the photoelectric conversion devices 1001 connected in series.

The output terminal 1014 is coupled to the other end of the photoelectric conversion devices 1001 connected in series.

### <Photovoltaic Power Generation System>

A photovoltaic power generation system appropriately converts electric power output from a photoelectric conversion module and supplies the power to a commercial electric power system or electrical equipment.

FIG. 14 is a schematic view of the structure of a photovoltaic power generation system according to an embodiment of the present invention that includes a photoelectric conversion device according to the present invention. Referring to FIG. 14, a photovoltaic power generation system 2000 according to the present invention includes a photoelectric conversion module array 2001, a junction box 2002, a power conditioner 2003, a distribution board 2004, and an electric power meter 2005. As described below, the photoelectric conversion module array 2001 is composed of a plurality of photoelectric conversion modules 1000 according to the present invention. A photoelectric conversion device according to the present invention has high conversion efficiency. Thus, a photovoltaic power generation system according to the present invention including the photoelectric conversion device can also have high conversion efficiency.

The photovoltaic power generation system 2000 may have a function called “home energy management system (HEMS)” or “building energy management system (BEMS)”. This allows monitoring of the electrical power output of the photovoltaic power generation system 2000 and monitoring and controlling of the power consumption of electrical equipment coupled to the photovoltaic power generation system 2000, thereby reducing energy consumption.

The junction box 2002 is coupled to the photoelectric conversion module array 2001. The power conditioner 2003 is coupled to the junction box 2002. The distribution board 2004 is coupled to the power conditioner 2003 and electrical equipment 2011. The electric power meter 2005 is coupled to the distribution board 2004 and a commercial electric power system.

As illustrated in FIG. 17, the power conditioner 2003 may be coupled to a storage battery 5001. This can reduce output fluctuations due to variations in the amount of sunlight and allows electric power stored in the storage battery 5001 to be supplied to the electrical equipment 2011 or a commercial electric power system even during the time when there is no sunshine. The storage battery 5001 may be disposed in the power conditioner 2003.

### <Operation>

The photovoltaic power generation system 2000 according to the present invention operates as described below, for example. The photoelectric conversion module array 2001 converts sunlight into electricity, generates direct-current power, and supplies the direct-current power to the junction box 2002.

The junction box 2002 receives the direct-current power from the photoelectric conversion module array 2001 and supplies the direct-current power to the power conditioner 2003.

The power conditioner 2003 converts the direct-current power received from the junction box 2002 into alternating-current power and supplies the alternating-current power to the distribution board 2004. Part of the direct-current power received from the junction box 2002 may be directly supplied to the distribution board 2004 without conversion to alternating-current power. In the presence of the storage battery 5001, the power conditioner 2003 may supply part or all of the electric power received from the junction box 2002 to the storage battery 5001 to store the electric power therein, or may be supplied with electric power from the storage battery 5001.

The distribution board 2004 supplies the electrical equipment 2011 with the electric power received from the power conditioner 2003 or commercial electric power received through the electric power meter 2005. When alternating-current power received from the power conditioner 2003 is more than the power consumption of the electrical equipment 2011, the distribution board 2004 supplies the alternating-current power received from the power conditioner 2003 to the electrical equipment 2011. The remainder of the alternating-current power is supplied to a commercial electric power system through the electric power meter 2005.

When alternating-current power received from the power conditioner 2003 is less than the power consumption of the electrical equipment 2011, the distribution board 2004 supplies the electrical equipment 2011 with alternating-current power received from a commercial electric power system and the alternating-current power received from the power conditioner 2003.

The electric power meter 2005 measures the electric power supplied from a commercial electric power system to the distribution board 2004 and the electric power supplied from the distribution board 2004 to a commercial electric power system.

### <Photoelectric Conversion Module Array>

The photoelectric conversion module array 2001 will be described below. FIG. 15 is a schematic view of a structure of the photoelectric conversion module array 2001 illustrated in FIG. 14. Referring to FIG. 15, the photoelectric conversion module array 2001 includes the photoelectric conversion modules 1000 and output terminals 2013 and 2014.

The photoelectric conversion modules 1000 are arranged in an array and are connected in series. Although the photoelectric conversion modules 1000 are arranged for series connection in FIG. 15, the arrangement and connection are not limited to this. The photoelectric conversion modules 1000 may be coupled in parallel or in a combination of series and parallel. The number of the photoelectric conversion modules 1000 in the photoelectric conversion module array 2001 may be an integer of 2 or more.

The output terminal 2013 is coupled to one end of the photoelectric conversion modules 1000 connected in series.

The output terminal 2014 is coupled to the other end of the photoelectric conversion modules 1000 connected in series.

The description above is only an example, and a photovoltaic power generation system according to the present invention is not limited to the description and may have any structure that includes at least one photoelectric conversion device according to the present invention.

### <Large-Scale Photovoltaic Power Generation System>

Large-scale photovoltaic power generation systems are greater in size than the photovoltaic power generation systems described above. A large-scale photovoltaic power generation system according to the present invention described below also includes a photoelectric conversion device according to the present invention.

FIG. 16 is a schematic view of the structure of a large-scale photovoltaic power generation system according to an embodiment of the present invention. Referring to FIG. 16, a large-scale photovoltaic power generation system 4000 according to the present invention includes a plurality of subsystems 4001, a plurality of power conditioners 4003, and a transformer 4004. The photovoltaic power generation system 4000 is greater in size than the photovoltaic power generation system 2000 according to the present invention illustrated in FIG. 14. A photoelectric conversion device according to the present invention has high conversion efficiency. Thus, a photovoltaic power generation system according to the present invention including the photoelectric conversion device can also have high conversion efficiency.

Each of the power conditioners 4003 is coupled to the corresponding subsystem 4001. In the photovoltaic power generation system 4000, the number of the power conditioners 4003 and the number of the subsystems 4001 coupled to the power conditioners 4003 may be an integer of 2 or more.

The transformer 4004 is coupled to the power conditioners 4003 and a commercial electric power system.

Each of the subsystems 4001 is composed of a plurality of module systems 3000. The number of the module systems 3000 in each of the subsystems 4001 may be an integer of 2 or more.

Each of the module systems 3000 includes a plurality of the photoelectric conversion module arrays 2001, a plurality of junction boxes 3002, and a collector box 3004. The number of the junction boxes 3002 in each of the module systems 3000 and the number of the photoelectric conversion module arrays 2001 coupled to the junction boxes 3002 may be an integer of 2 or more.

The collector box 3004 is coupled to the junction boxes 3002. Each of the power conditioners 4003 is coupled to the collector boxes 3004 of each of the subsystems 4001.

### <Operation>

The photovoltaic power generation system 4000 operates as described below. The photoelectric conversion module arrays 2001 in each of the module systems 3000 convert sunlight into electricity, generates direct-current power, and supplies the direct-current power to the collector box 3004 through the junction boxes 3002. The collector boxes 3004 in the subsystems 4001 supply the direct-current power to the power conditioners 4003. The power conditioners 4003 convert the direct-current power into alternating-current power and supply the alternating-current power to the transformer 4004.

The transformer 4004 changes the voltage level of the alternating-current power received from the power conditioners 4003 and supplies the alternating-current power to a commercial electric power system.

### MODIFIED EXAMPLES

As illustrated in FIG. 18, in the large-scale photovoltaic power generation system 4000 according to the present invention, each of the power conditioners 4003 may be coupled to the storage battery 5001. This can reduce output fluctuations due to variations in the amount of sunlight and allows electric power stored in the storage battery 5001 to be supplied to a commercial electric power system even during the time when there is no sunshine. The storage battery 5001 may be disposed in the power conditioner 4003.

Provided that the photovoltaic power generation system 4000 includes a photoelectric conversion device according to the present invention, all the photoelectric conversion devices in the photovoltaic power generation system 4000 are not necessarily photoelectric conversion devices according to the present invention. For example, all the photoelectric conversion devices in one of the subsystems 4001 may be photoelectric conversion devices according to the present invention, and part or all of the photoelectric conversion devices in another subsystem 4001 may not be a photoelectric conversion device according to the present invention. The storage battery 5001 may be disposed in the power conditioner 4003.

A core-shell particle, an upconversion layer, and a photoelectric conversion device according to the present invention are more specifically described below with examples. However, it goes without saying that the present invention is not limited to these examples.

### Examples

### <Formation of Semiconductor Core>

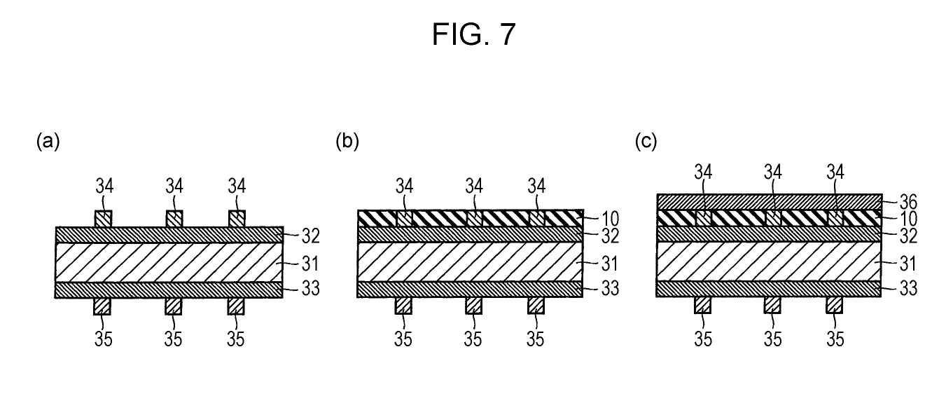

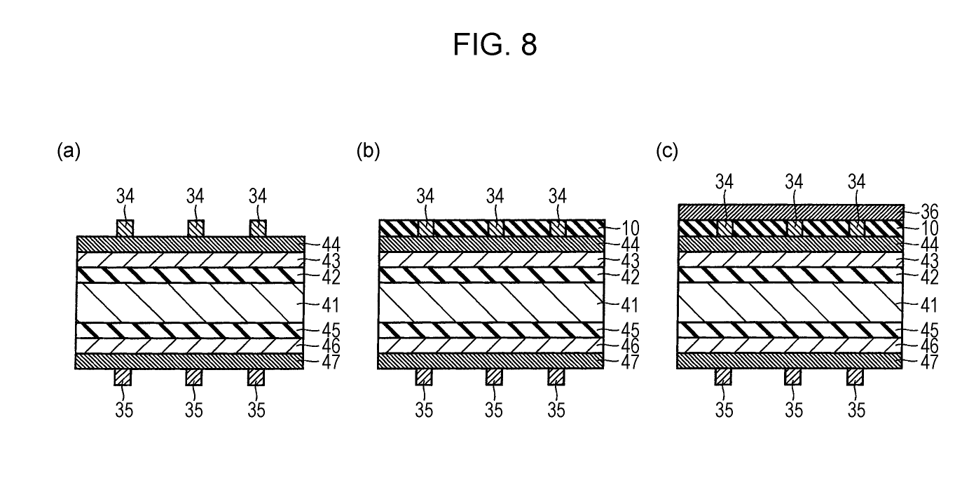

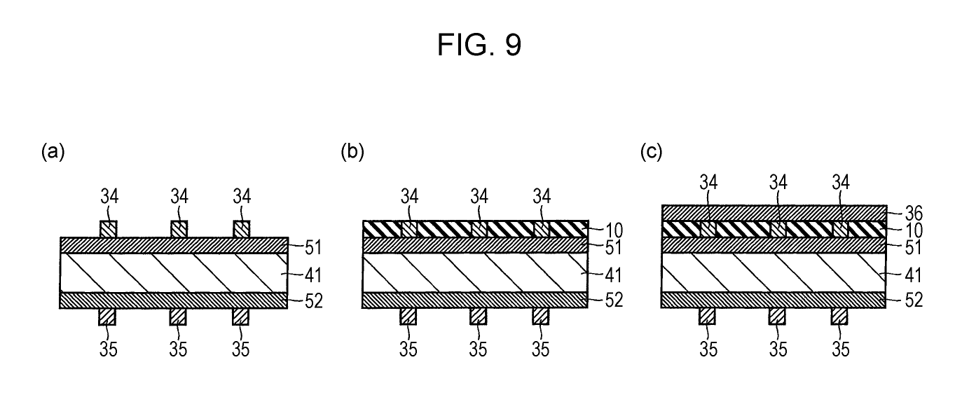

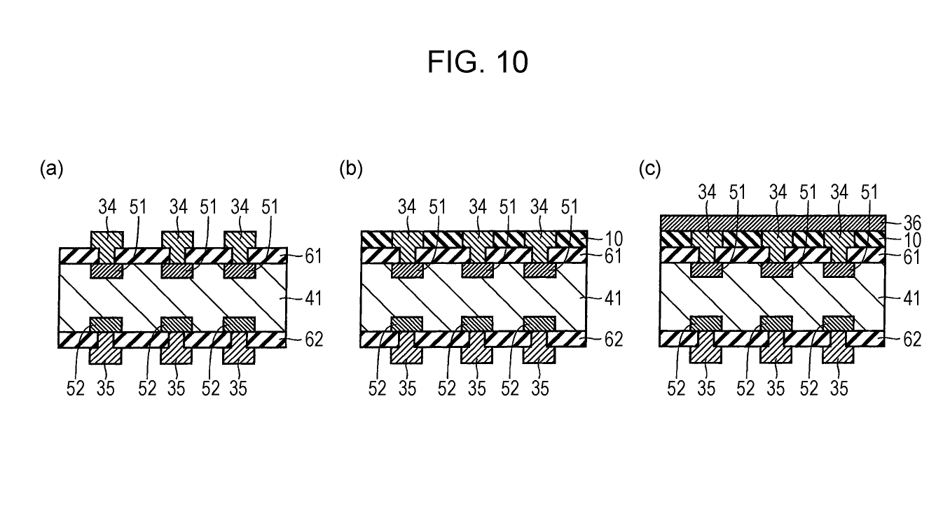

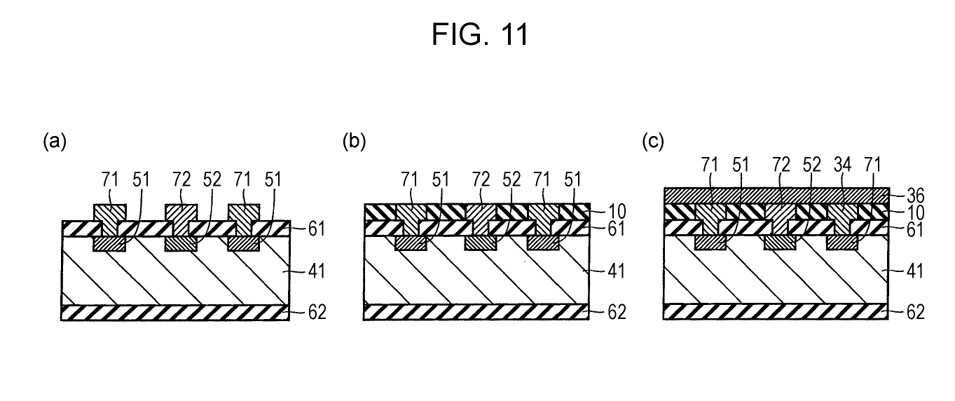

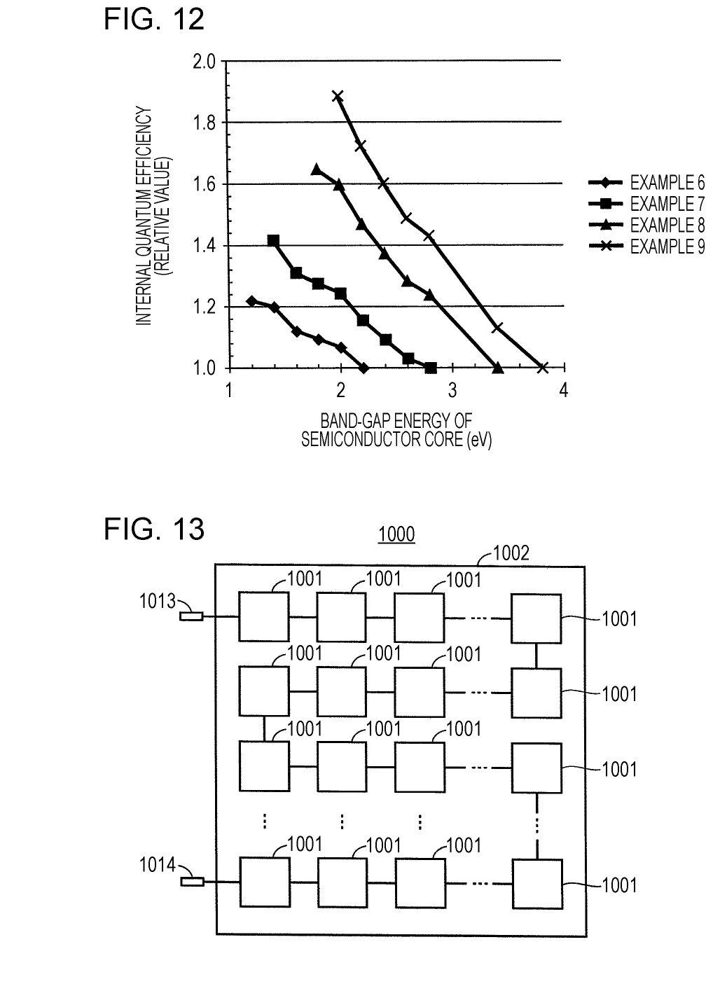

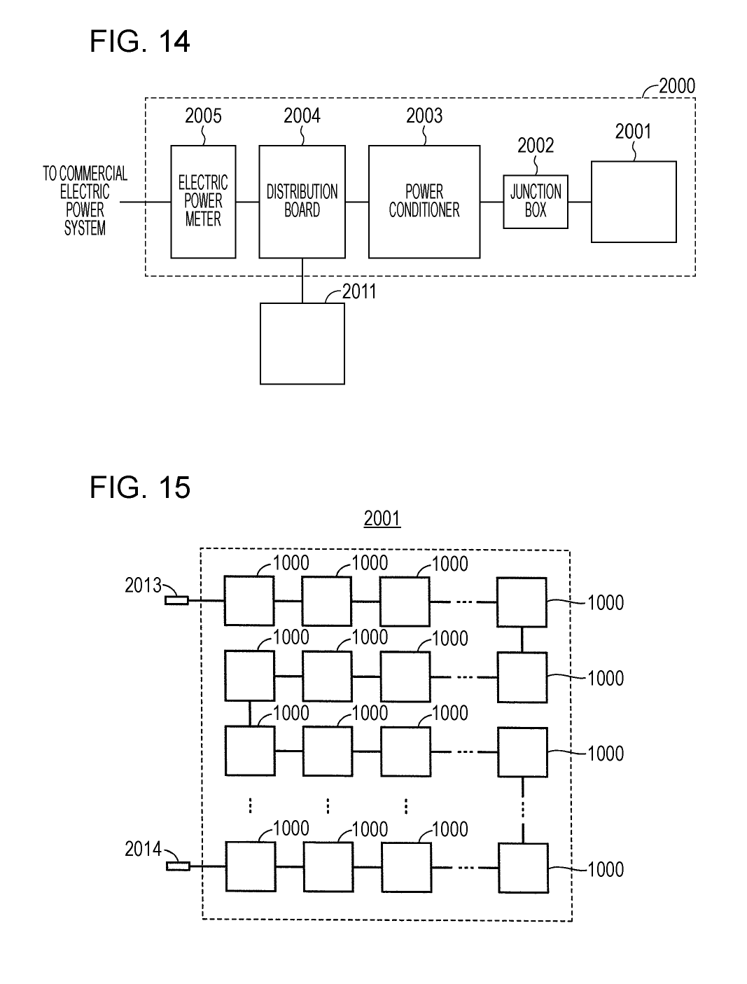

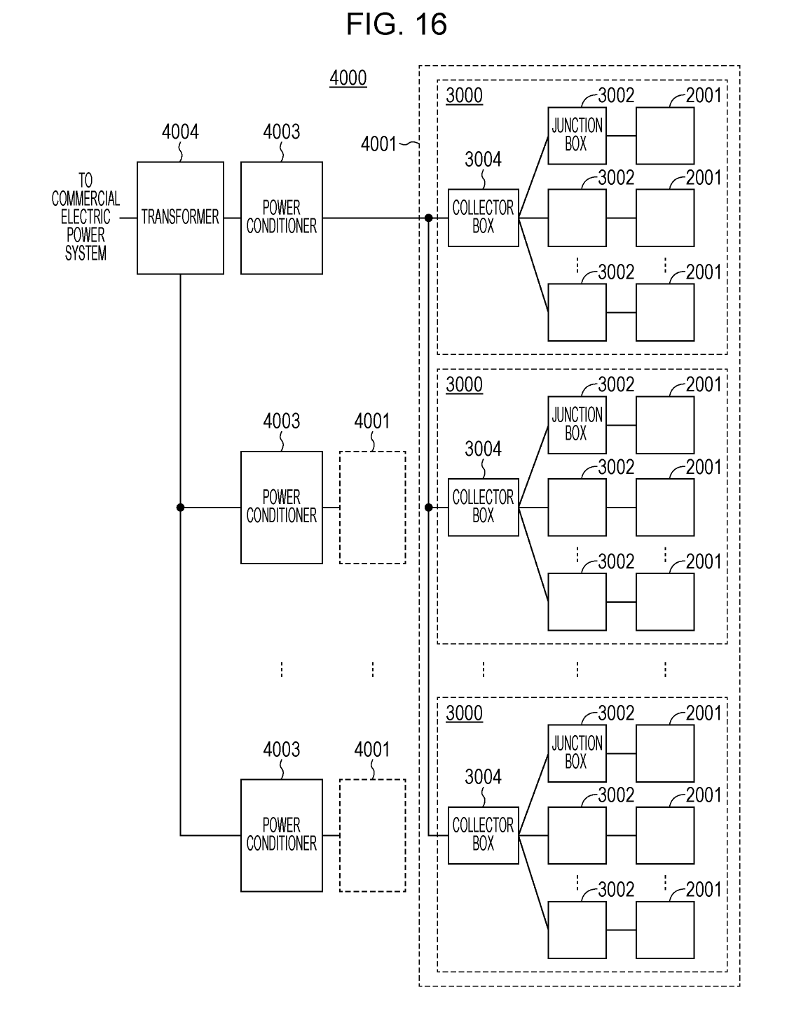

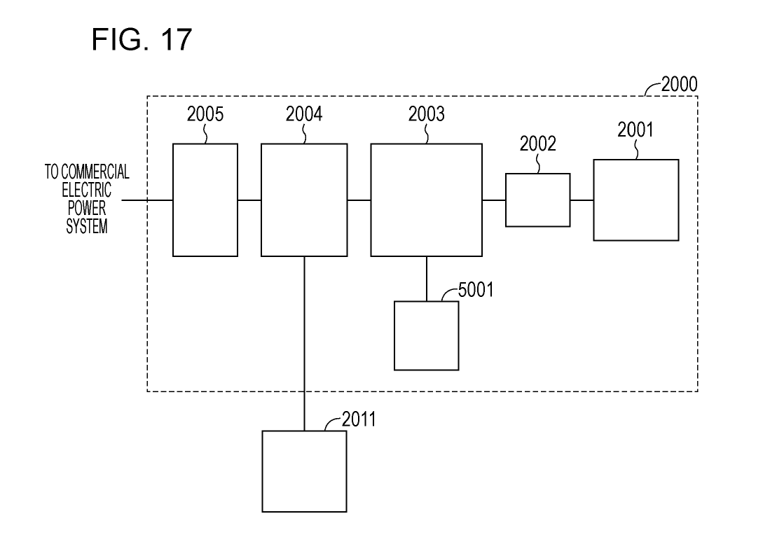

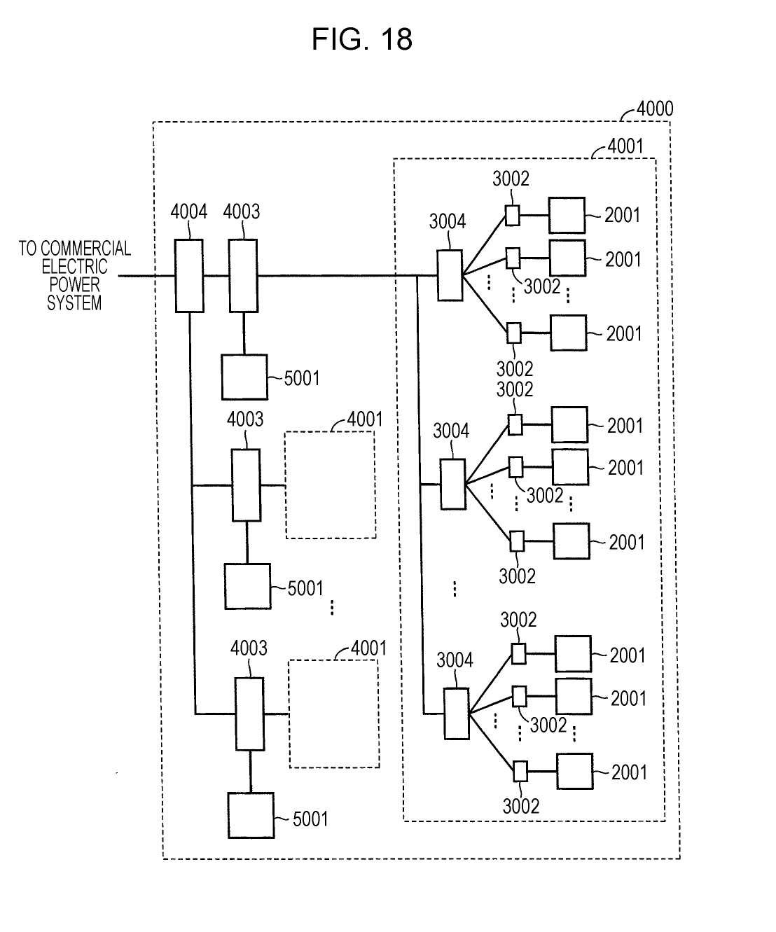

First, as illustrated in a schematic side view of FIG. 6, a flask 26 was charged with 0.5 mmol (millimole) of CuCl, 0.47 mmol of GaC₃, 1 mmol of S, 0.03 mol of bis(2,4-pentanedionato)tin(IV) dichloride, and 15 ml of 70% oleylamine in an argon atmosphere to prepare a solution 20 for use in the formation of a semiconductor core.

The flask 26 was then placed in a mantle heater 24 and was coupled to a Schlenk line (not shown) through a cooler 21. The atmosphere was prevented from entering the flask 26.

Evacuation and nitrogen substitution of the flask 26 were alternately performed three times with a vacuum pump and a nitrogen gas supply pipe coupled to the Schlenk line.

Next, while stirring the solution 20 with a magnetic stirrer 23, the solution 20 was heated in the mantle heater 24 to a temperature of 130° C. as read on a thermometer 22 and was held for 1 hour.

The solution 20 was then slowly heated to a temperature of 265° C. at a heating rate of approximately 2.5° C./min in the mantle heater 24 and was held for 1.5 hours. The semiconductor core 1 was grown in the solution 20. The flask 26 was then immersed and rapidly cooled in a water bath (not shown).

Then, 1 ml of oleylamine, toluene, and ethanol were added to the flask 26 in this order. After centrifugation, the supernatant liquid was discarded for purification. The purification was performed three times. A semiconductor core represented by the formula CuGaS₂:Sn, which was composed of a semiconductor represented by the formula CuGaS₂ and an impurity Sn that forms an intermediate band in a band gap of the semiconductor, was formed as a precipitate. The average particle size of the semiconductor core thus formed was 11 nm as determined with a transmission electron microscope.

### <Formation of First Semiconductor Shell>

First, 0.5 mmol of CuCl, 0.5 mmol of GaCl₃, and 1 mmol of S were dissolved in 15 ml of 70% oleylamine in an argon atmosphere to prepare a solution for use in the formation of a first semiconductor shell.

Oleylamine was then added to the semiconductor core formed as a precipitate as described above to prepare a dispersion liquid A containing the semiconductor core dispersed in oleylamine. The dispersion liquid A was transferred into a syringe.

The dispersion liquid A was then poured into a flask. The flask was placed in a mantle heater and was coupled to a Schlenk line. Evacuation and nitrogen substitution of the flask were alternately performed three times with a vacuum pump and a nitrogen gas supply pipe coupled to the Schlenk line.

The solution for use in the formation of the first semiconductor shell prepared as described above was then added dropwise to the flask containing the dispersion liquid A heated to 265° C. in the mantle heater. The temperature of the solution in the flask was then decreased to room temperature (25° C.)

Then, 1 ml of oleylamine, toluene, and ethanol were added to the flask in this order. After centrifugation, the supernatant liquid was discarded for purification. The purification was performed three times. A particle (CuGaS₂:Sn/CuGaS₂) having a structure in which the first semiconductor shell represented by the formula CuGaS₂ was formed on the surface of the semiconductor core represented by the formula CuGaS₂:Sn was formed as a precipitate. The thickness of the first semiconductor shell thus formed was 8 nm as determined with a transmission electron microscope.

The band gap of the first semiconductor shell can become narrower than the band gap of the semiconductor core through one of (i) substitution of InCl₃ or the like for at least part of GaCl₃, (ii) substitution of Se for at least part of S, and (iii) (i) and (ii). More specifically, substitution of In for part of Ga of CuGaS₂ can shift the lower end of the conduction band of the first semiconductor shell toward the intermediate band of the semiconductor core, and substitution of Se for part of S of CuGaS₂ can shift the upper end of the valence band of the first semiconductor shell toward the intermediate band of the semiconductor core. This allows carriers generated by irradiation with excitation light in the semiconductor core to flow into the first semiconductor shell and suppresses backflow of the carriers from the first semiconductor shell to the semiconductor core, thus increasing the amount of light emitted from the first semiconductor shell.

### <Formation of Second Semiconductor Shell>

A solution for use in the formation of a second semiconductor shell was prepared by dissolving 0.1 mol/l zinc stearate and sulfur in a mixed solution of oleylamine and octadecene mixed at a volume ratio of 4:1.

Oleylamine was added to particles having a structure in which the first semiconductor shell represented by the formula CuGaS₂ was formed on the surface of the semiconductor core formed as a precipitate as described above and represented by the formula CuGaS₂:Sn to prepare a dispersion liquid B containing the particles dispersed in oleylamine.

The dispersion liquid B was then poured into a flask. The flask was placed in a mantle heater. The dispersion liquid B was heated to 80° C. in the mantle heater. The solution for use in the formation of the second semiconductor shell was added dropwise to the flask.

The solution in the flask was then heated to a temperature of 210° C. in the mantle heater and was held for 30 minutes. The temperature of the solution in the flask was then decreased to room temperature (25° C.)

Then, 1 ml of oleylamine, toluene, and ethanol were added to the flask in this order. After centrifugation, the supernatant liquid was discarded for purification. The purification was performed three times. Thus, a core-shell particle (CuGaS₂:Sn/CuGaS₂/ZnS) according to an example was formed as a precipitate. The core-shell particle had a structure in which the first semiconductor shell represented by the formula CuGaS₂ was disposed on the surface of the semiconductor core represented by the formula CuGaS₂:Sn, and the second semiconductor shell represented by the formula ZnS was disposed on the surface of the first semiconductor shell. The thickness of the second semiconductor shell of the core-shell particle according to the example thus formed was 8 nm as determined with a transmission electron microscope.

<Production of Photovoltaic Cell according to Example 1>

FIGS. 7(a) to 7(c) are schematic cross-sectional views illustrating a method for producing a photovoltaic cell according to Example 1. As illustrated in FIG. 7(a), a sample prepared includes a first carrier collecting electrode 33 on a light-receiving surface of a photoelectric conversion layer 31, light-receiving surface side electrodes 35 on the first carrier collecting electrode 33, a second carrier collecting electrode 32 on the back side of the photoelectric conversion layer 31, and back-side electrodes 34 on the second carrier collecting electrode 32. The sample having the structure illustrated in FIG. 7(a) is referred to as a sample A.

The material of the photoelectric conversion layer 31 was determined to have a structure in which a p-type dopant was diffused in a light-receiving surface of a n-type polycrystalline silicon substrate to form a p-layer such that the band gap of a first semiconductor shell of a core-shell particle according to an example was greater than or equal to the band gap of the photoelectric conversion layer 31. Thus, the first carrier is a positive hole, and the second carrier is an electron.

The core-shell particles according to the example thus formed were then dispersed in toluene to prepare a dispersion liquid C. The dispersion liquid C was applied to the back side of the photoelectric conversion layer 31 and was dried to form an upconversion layer 10 on the back side of the photoelectric conversion layer 31, as illustrated in FIG. 7(b). The sample having the structure illustrated in FIG. 7(b) is referred to as a sample B.

As illustrated in FIG. 7(c), a reflective metal film 36 formed of a Ag film was then formed on the back side of the upconversion layer 10, thus producing a photovoltaic cell according to Example 1. The sample having the structure illustrated in FIG. 7(c) is referred to as a sample C.

In the photovoltaic cell according to Example 1 thus produced, light passing through the upconversion layer 10 and light emitted from the upconversion layer 10 in the direction of the reflective metal film 36 can be reflected toward the photoelectric conversion layer 31, thereby improving photoelectric conversion efficiency. The reflective metal film 36 was electrically connected to the back-side electrodes 34, resulting in low parasitic resistance. This can further improve the photoelectric conversion efficiency of the photovoltaic cell according to Example 1. The material of the reflective metal film 36 may be an Al film instead of the Ag film. The reflective metal film 36 can be formed by printing a metal paste by a screen printing method and baking the metal paste, or can be formed by a vapor deposition method.

The internal quantum efficiency and short-circuit current density of the samples A to C were calculated and compared. Table 1 shows the results. The internal quantum efficiency and short-circuit current density in Table 1 are relative values based on the internal quantum efficiency and short-circuit current density of the sample A, which are taken as 1.

The internal quantum efficiency and short-circuit current density of the samples A to C were calculated under the conditions that the band-gap energy of the photoelectric conversion layer 31 of the samples A to C was 1.1 eV and that the band gap of the semiconductor core of the core-shell particle according to the example was 1.2 eV (a band-gap energy difference of 0.6 eV between the valence band of the semiconductor constituting the semiconductor core of the core-shell particle according to the example and the intermediate band formed by an impurity, and a band-gap energy difference of 0.6 eV between the conduction band of the semiconductor constituting the semiconductor core of the core-shell particle according to the example and the intermediate band formed by the impurity).

TABLE 1

| | Sample A | Sample B | Sample C |
|---|---|---|---|
| Internal quantum | 1 | 1.11 | 1.22 |
| efficiency | | | |
| Short-circuit | 1 | 1.11 | 1.22 |
| current density | | | |

Table 1 shows that the formation of the upconversion layer 10 containing the core-shell particle according to the example improved the internal quantum efficiency and short-circuit current density. The formation of the upconversion layer 10 together with the reflective metal film 36 further improved the internal quantum efficiency and short-circuit current density.

<Production of Photovoltaic Cell according to Example 2>

FIGS. 8(a) to 8(c) are schematic cross-sectional views illustrating a method for producing a photovoltaic cell according to Example 2. First, as illustrated in FIG. 8(a), an undoped i-type hydrogenated amorphous silicon thin film 45 having a thickness in the range of 3 to 10 nm and a n-type hydrogenated amorphous silicon thin film 46 having a thickness in the range of 3 to 10 nm were stacked in this order on a surface on the light-receiving surface side of the n-type silicon substrate 41 by a plasma CVD method. An undoped i-type hydrogenated amorphous silicon thin film 42 having a thickness in the range of 3 to 10 nm and a p-type hydrogenated amorphous silicon thin film 43 having a thickness in the range of 3 to 10 nm were stacked in this order on a surface on the back side of the n-type silicon substrate 41. Transparent electrically conductive films 44 and 47 having a thickness in the range of 70 to 100 nm and made of indium tin oxide (ITO) were then formed on surfaces of a p-type hydrogenated amorphous silicon thin film 43 and a p-type hydrogenated amorphous silicon thin film 46 by a sputtering method. A silver paste was then applied to the transparent electrically conductive films 44 and 47 by a screen printing method, was dried, and was baked to form back-side electrodes 34 on the transparent electrically conductive film 44 and light-receiving surface side electrodes 35 on the transparent electrically conductive film 47.

As illustrated in FIG. 8(b), the dispersion liquid C was then applied to a surface of the transparent electrically conductive film 44 and was dried to form an upconversion layer 10.

As illustrated in FIG. 8(c), a reflective metal film 36 formed of a Ag film was then formed on the upconversion layer 10, thus producing a photovoltaic cell according to Example 2. Also in the photovoltaic cell according to Example 2 thus produced, light passing through the upconversion layer 10 and light emitted from the upconversion layer 10 in the direction of the reflective metal film 36 can be reflected toward the photoelectric conversion layer 31, thereby improving photoelectric conversion efficiency.

<Production of Photovoltaic Cell according to Example 3>

FIGS. 9(a) to 9(c) are schematic cross-sectional views illustrating a method for producing a photovoltaic cell according to Example 3. First, as illustrated in FIG. 9(a), a p-type impurity diffusion layer 52 containing a p-type impurity diffused therein and a n-type impurity diffusion layer 51 containing a n-type impurity diffused therein were formed on a light-receiving surface and the back side of a n-type silicon substrate 41, respectively. Light-receiving surface side electrodes 35 and back-side electrodes 34 were formed on the p-type impurity diffusion layer 52 and the n-type impurity diffusion layer 51, respectively.

As illustrated in FIG. 9(b), the dispersion liquid C was then applied to the back side of the n-type silicon substrate 41 and was dried to form an upconversion layer 10.

As illustrated in FIG. 9(c), a reflective metal film 36 formed of a Ag film was then formed on the upconversion layer 10, thus producing a photovoltaic cell according to Example 3. Also in the photovoltaic cell according to Example 3 thus produced, light passing through the upconversion layer 10 and light emitted from the upconversion layer 10 in the direction of the reflective metal film 36 can be reflected toward the photoelectric conversion layer, that is, toward the n-type silicon substrate 41 on which the n-type impurity diffusion layer 51 and the p-type impurity diffusion layer 52 were formed, thereby improving photoelectric conversion efficiency.

### <Production of Photovoltaic Cell According to Example 4>

FIGS. 10(a) to 10(c) are schematic cross-sectional views illustrating a method for producing a photovoltaic cell according to Example 4. First, as illustrated in FIG. 10(a), a p-type impurity diffusion layer 52 containing a p-type impurity diffused therein and a n-type impurity diffusion layer 51 containing a n-type impurity diffused therein were formed on part of a light-receiving surface and part of the back side of a n-type silicon substrate 41, respectively. Passivation films 62 and 61 were formed on the light-receiving surface and the back side of the n-type silicon substrate 41 such that part of the p-type impurity diffusion layer 52 and part of the n-type impurity diffusion layer 51 were exposed. Back-side electrodes 34 and light-receiving surface side electrodes 35 were then formed in contact with the n-type impurity diffusion layer 51 and the p-type impurity diffusion layer 52.

As illustrated in FIG. 10(b), the dispersion liquid C was then applied to the back side of the n-type silicon substrate 41 and was dried to form an upconversion layer 10.

As illustrated in FIG. 10(c), a reflective metal film 36 formed of a Ag film was then formed on the upconversion layer 10, thus producing a photovoltaic cell according to Example 4. Also in the photovoltaic cell according to Example 4 thus produced, light passing through the upconversion layer 10 and light emitted from the upconversion layer 10 in the direction of the reflective metal film 36 can be reflected toward the photoelectric conversion layer, that is, toward the n-type silicon substrate 41 on which the n-type impurity diffusion layer 51 and the p-type impurity diffusion layer 52 were formed, thereby improving photoelectric conversion efficiency.

### <Production of Photovoltaic Cell According to Example 5>

FIGS. 11(a) to 11(c) are schematic cross-sectional views illustrating a method for producing a photovoltaic cell according to Example 5. First, as illustrated in FIG. 11(a), a p-type impurity diffusion layer 52 containing a p-type impurity diffused therein and a n-type impurity diffusion layer 51 containing a n-type impurity diffused therein were alternately formed on the back side of a n-type silicon substrate 41, respectively. A passivation film 61 was then formed on the back side of the n-type silicon substrate 41 such that part of the p-type impurity diffusion layer 52 and part of the n-type impurity diffusion layer 51 were exposed. A passivation film 62 was formed on a light-receiving surface of the n-type silicon substrate 41. Then, n-electrodes 71 and p-electrodes 72 were formed in contact with the n-type impurity diffusion layers 51 and the p-type impurity diffusion layers 52.

As illustrated in FIG. 11(b), the dispersion liquid C was then applied to the back side of the n-type silicon substrate 41 and was dried to form an upconversion layer 10.

As illustrated in FIG. 11(c), a reflective metal film 36 formed of a Ag film was then formed on the upconversion layer 10, thus producing a photovoltaic cell according to Example 5. Also in the photovoltaic cell according to Example 5 thus produced, light passing through the upconversion layer 10 and light emitted from the upconversion layer 10 in the direction of the reflective metal film 36 can be reflected toward the photoelectric conversion layer, that is, toward the n-type silicon substrate 41 on which the n-type impurity diffusion layers 51 and the p-type impurity diffusion layers 52 were formed, thereby improving photoelectric conversion efficiency.

### <Production of Photovoltaic Cells According to Examples 6 to 9>

Photovoltaic cells according to Examples 6 to 9 were produced by only changing the band-gap energy of the photoelectric conversion layer 31 of the photovoltaic cell having the structure illustrated in FIG. 7(c). The band-gap energy of the photoelectric conversion layer 31 of the photovoltaic cells according to Examples 6 to 9 was 1.1 eV (Example 6), 1.4 eV (Example 7), 1.7 eV (Example 8), and 1.9 eV (Example 9).

In the photovoltaic cells according to Examples 6 to 9 thus produced, changes in internal quantum efficiency were calculated by changing the band-gap energy of semiconductor cores of core-shell particles in the upconversion layer 10. FIG. 12 shows the results.

The internal quantum efficiency of the photovoltaic cells according to Examples 6 to 9 was calculated on the assumption that sunlight having an air mass (AM) of 1.5 was used as standard sunlight. The intermediate band of the semiconductor core was assumed to be disposed in the middle of the band gap of the semiconductor constituting the semiconductor core. The absorption coefficient for the standard sunlight between the upper end of the valence band of the band gap of the semiconductor constituting the semiconductor core and the intermediate band was assumed to be the same as the absorption coefficient for the standard sunlight between the intermediate band and the lower end of the conduction band of the band gap of the semiconductor constituting the semiconductor core. The internal quantum efficiency shown in FIG. 12 for the photovoltaic cells according to Examples 6 to 9 is a relative value based on the case that the upconversion layer 10 was not formed, which is assumed to have internal quantum efficiency of 1.

FIG. 12 shows that any of the photovoltaic cells according to Examples 6 to 9 had improved internal quantum efficiency due to the formation of the upconversion layer 10. An increase in internal quantum efficiency results in a proportional increase in short-circuit current density and improved photoelectric conversion efficiency.

### <Conclusions>

The present invention provides a core-shell particle that includes a semiconductor core and a first semiconductor shell on a surface of the semiconductor core, wherein the semiconductor core contains a semiconductor and an impurity that forms an intermediate band in a band gap of the semiconductor. In such a structure, when excitation light enters the semiconductor constituting the semiconductor core, an electron in the valence band in the semiconductor core absorbs light having a wavelength corresponding to the energy difference between the intermediate band and the valence band and light having a wavelength corresponding to the energy difference between the conduction band and the intermediate band and is excited to the conduction band via the intermediate band, forming an electron-hole pair. The electron-hole pair flows into the first semiconductor shell, recombines, and emits light having a wavelength corresponding to the band gap of the first semiconductor shell, thus performing upconversion.

In a core-shell particle according to the present invention, the first semiconductor shell is preferably a direct transition semiconductor. In such a structure, an electron upconverted by irradiation with excitation light in the semiconductor core can recombine with a positive hole in the first semiconductor shell and emit light having a shorter wavelength than the excitation light.

In a core-shell particle according to the present invention, the band gap of the first semiconductor shell is preferably narrower than the band gap of the semiconductor core. Such a structure allows carriers generated by upconversion in the semiconductor core to flow easily into the first semiconductor shell and can effectively prevent the carriers from flowing backward from the first semiconductor shell to the semiconductor core. This can increase the amount of light emitted from the first semiconductor shell and improve the photoelectric conversion efficiency of a photoelectric conversion device including a core-shell particle according to the present invention.

In a core-shell particle according to the present invention, the lower end of the conduction band and the upper end of the valence band of the first semiconductor shell are preferably closer to the intermediate band than the corresponding lower end of the conduction band and the corresponding upper end of the valence band of the semiconductor core. Such a structure allows carriers generated by upconversion in the semiconductor core to flow easily into the first semiconductor shell and can effectively prevent the carriers from flowing backward from the first semiconductor shell to the semiconductor core.

This can increase the amount of light emitted from the first semiconductor shell and improve the photoelectric conversion efficiency of a photoelectric conversion device including a core-shell particle according to the present invention.

In a core-shell particle according to the present invention, the semiconductor of the semiconductor core preferably contains copper, at least one of gallium and indium, and at least one of sulfur and selenium, and the impurity in the semiconductor core preferably contains at least one selected from the group consisting of carbon, silicon, germanium, tin, titanium, iron, and chromium. Such a structure can efficiently excite electrons by irradiation with excitation light in the semiconductor core and can further improve upconversion efficiency.

In a core-shell particle according to the present invention, the first semiconductor shell preferably contains copper, at least one of gallium and indium, and at least one of sulfur and selenium. Such a structure allows an electron excited from the valence band to the conduction band by irradiation with excitation light in the semiconductor core to recombine with a positive hole in the first semiconductor shell and can efficiently convert the excitation light into light having a shorter wavelength than the excitation light before the light enters a photoelectric conversion layer of a photoelectric conversion device. Thus, the photoelectric conversion device can have further improved photoelectric conversion efficiency.

In a core-shell particle according to the present invention, the indium or selenium content of the first semiconductor shell is higher than that of the semiconductor core. In such a structure, the band gap of the first semiconductor shell is narrower than the band gap of the semiconductor constituting the semiconductor core, and the lower end of the conduction band and the upper end of the valence band of the first semiconductor shell are closer to the intermediate band than the corresponding lower end of the conduction band and the corresponding upper end of the valence band of the semiconductor constituting the semiconductor core. This allows carriers generated in the semiconductor core to flow easily into the first semiconductor shell and can more effectively prevent the carriers from flowing backward from the first semiconductor shell to the semiconductor core.

A core-shell particle according to the present invention preferably further includes a second semiconductor shell on the surface of the first semiconductor shell. Such a structure can prevent the formation of a surface level on an outer surface of the first semiconductor shell (opposite the semiconductor core) and prevent non-luminescent recombination of carriers via the surface level, thereby increasing the amount of light emitted from the first semiconductor shell.

In a core-shell particle according to the present invention, the band gap of the second semiconductor shell is preferably wider than the band gap of the first semiconductor shell. The second semiconductor shell having such a structure can more effectively prevent carriers from flowing from the first semiconductor shell.

In a core-shell particle according to the present invention, the lower end of the conduction band and the upper end of the valence band of the second semiconductor shell are preferably more distant from the intermediate band than the corresponding lower end of the conduction band and the corresponding upper end of the valence band of the first semiconductor shell. The second semiconductor shell having such a structure can more effectively prevent carriers from flowing from the first semiconductor shell.

In a core-shell particle according to the present invention, the second semiconductor shell preferably contains zinc and sulfur. In such a structure, the band gap of the second semiconductor shell is wider than the band gap of the first semiconductor shell, and the lower end of the conduction band and the upper end of the valence band of the second semiconductor shell are more distant from the intermediate band than the corresponding lower end of the conduction band and the corresponding upper end of the valence band of the first semiconductor shell. This can more effectively prevent carriers in the first semiconductor shell from flowing from the second semiconductor shell. This can also effectively suppress the formation of an interface state at the interface between the first semiconductor shell and the second semiconductor shell and can suppress non-luminescent recombination of carriers via the interface state.

The present invention also provides an upconversion layer containing any of the core-shell particles described above. Such a structure can provide an upconversion layer that can improve upconversion efficiency and improve the photoelectric conversion efficiency of photoelectric conversion devices.

The present invention also provides a photoelectric conversion device that includes a photoelectric conversion layer and the upconversion layer disposed on a surface of the photoelectric conversion layer. Such a structure can provide a photoelectric conversion device that can improve upconversion efficiency and photoelectric conversion efficiency.

Although the embodiments and examples of the present invention have been described above, appropriate combinations of the constituents of the embodiments and examples are also originally envisaged.

It is to be understood that the embodiments and examples described above are illustrated by way of example and not by way of limitation in all respects. The scope of the present invention is defined by the appended claims rather than by the description preceding them. All modifications that fall within the scope of the claims and the equivalents thereof are therefore intended to be embraced by the claims.

### INDUSTRIAL APPLICABILITY

The present invention can be utilized in core-shell particles, upconversion layers, and photoelectric conversion devices and, in particular, can be suitably utilized in core-shell particles for solar cells, upconversion layers for solar cells, and solar cells including these.

### REFERENCE SIGNS LIST

1 Semiconductor core

1a Band gap of semiconductor constituting semiconductor core

2 First semiconductor shell

2a Band gap of first semiconductor shell

3 Second semiconductor shell

3a Band gap of second semiconductor shell

4 Intermediate band

5 Excitation light

6 Light

7 Photoelectric conversion layer

8 Light-receiving surface side electrode

10 Upconversion layer

11 Back-side electrode

20 Solution

21 Cooler

22 Thermometer

23 Magnetic stirrer

24 Mantle heater

26 Flask

31 Photoelectric conversion layer

32 Second carrier collecting electrode

33 First carrier collecting electrode

34 Back-side electrode

35 Light-receiving surface side electrode

36 Reflective metal film

41 n-type silicon substrate

42, 45 i-type hydrogenated amorphous silicon thin film

43 p-type hydrogenated amorphous silicon thin film

44, 47 Transparent electrically conductive film

46 n-type hydrogenated amorphous silicon thin film

51 n-type impurity diffusion layer

52 p-type impurity diffusion layer

61, 62 Passivation film

71 n-electrode

72 p-electrode

1000 Photoelectric conversion module

1001 Photoelectric conversion device

1002 Cover

1013, 1014 Output terminal

2000 Photovoltaic power generation system

2001 Photoelectric conversion module array

2002 Junction box

2003 Power conditioner

2004 Distribution board

2005 Electric power meter

2011 Electrical equipment

2013, 2014 Output terminal

3000 Module system

3002 Junction box

3004 Collector box

4000 Photovoltaic power generation system

4001 Subsystem

4003 Power conditioner

4004 Transformer

5001 Storage battery.

1. A core-shell particle, comprising:
a semiconductor core; and
a first semiconductor shell on a surface of the semiconductor core,
wherein the semiconductor core contains a semiconductor and an impurity that forms an intermediate band in a band gap of the semiconductor.

2. The core-shell particle according to claim 1, wherein the first semiconductor shell has a narrower band gap than the semiconductor core.

3. The core-shell particle according to claim 1, further comprising a second semiconductor shell on a surface of the first semiconductor shell.

4. An upconversion layer, comprising the core-shell particle according to claim 1.

5. A photoelectric conversion device, comprising:
a photoelectric conversion layer; and
the upconversion layer according to claim 4 on a surface of the photoelectric conversion layer.
